(19) United States
(12) Patent Application Publication
(10) Pub. No.: US 2023/0163001 A1
(43) Pub. Date: May 25, 2023

(54) METHOD TO ELIMINATE FIRST WAFER EFFECTS ON SEMICONDUCTOR PROCESS CHAMBERS

(71) Applicant: Applied Materials, Inc., Santa Clara, CA (US)

(72) Inventors: Martin Hilkene, Gilroy, CA (US); Huy Q. Nguyen, San Jose, CA (US); Kartik Shah, Saratoga, CA (US)

(21) Appl. No.: 17/534,116

(22) Filed: Nov. 23, 2021

(51) Int. Cl. H01L 21/67; G05B 19/406

(52) U.S. Cl. CPC H01L 21/67276; G05B 19/406

(57) ABSTRACT

Embodiments disclosed herein include methods for monitoring chamber performance in order to mitigate first wafer effects. In an embodiment, a method for determining an optimum chamber condition comprises monitoring a parameter during execution of a recipe for a number of substrates after the chamber has been in an idle state. In an embodiment, the method further comprises determining when a repeatability of the parameter meets a stability specification. In an embodiment, the method may continue with recording the parameter.

### BACKGROUND

### 1) Field

Embodiments relate to the field of semiconductor manufacturing and, in particular, to a process to mitigate first wafer effects in semiconductor processing chambers.

### 2) Description of Related Art

Process chambers in semiconductor manufacturing environments are carefully calibrated in order to provide precise outcomes on substrates (e.g., wafers) that are processed in the chamber. Process chambers that have been idle will drift away from their optimum operating conditions. Substrates that are processed immediately after the idling condition often show differences in film properties or other processing properties. Such drifting away from the desired outcome is often referred to as a first wafer effect (FWE).

To minimize the FWE, chambers can run cyclic conditioning recipes. In such recipes, dummy substrates are cycled through the chamber. While such processes may mitigate FWEs, such processing comes at a cost. For example, increases in operating costs are observed due to the cost of powering the chamber, the cost of consumable materials (e.g., gasses), and the cost of dummy substrates.

### SUMMARY

Embodiments disclosed herein include methods for monitoring chamber performance in order to mitigate first wafer effects. In an embodiment, a method for determining an optimum chamber condition comprises monitoring a parameter during execution of a recipe for a number of substrates after the chamber has been in an idle state. In an embodiment, the method further comprises determining when a repeatability of the parameter meets a stability specification. In an embodiment, the method may continue with recording the parameter.

Methods may also include a method of warming up a chamber in some embodiments. In an embodiment, the method comprises retrieving stored sensor data that indicates an endpoint of a warmup routine. In an embodiment, the method may then include initiating the warmup routine when sensor data is below a value of the stored sensor data. In an embodiment, the method may further include stopping the warmup routine when the sensor data is equal to or greater than the value of the stored sensor data.

In an embodiment, a method of warming up a chamber may comprise retrieving stored virtual sensor data that indicates an endpoint of a warmup routine. In an embodiment, the stored virtual sensor data is a calculated value based on the readings of two or more physical sensors. In an embodiment, the method may further comprise initiating the warmup routine when virtual sensor data is below a value of the stored virtual sensor data. In an embodiment, the warmup routine comprises turning on one or more lamps. In an embodiment, the method may further comprise stopping the warmup routine when the virtual sensor data is equal to or greater than the value of the stored virtual sensor data.

### BRIEF DESCRIPTION OF THE DRAWINGS

FIG. 1 is a graph of the recorded value of a sensor during a process recipe for the processing of a plurality of substrates after a chamber idling event, in accordance with an embodiment.

FIG. 2A is a line scan across the surface of a plurality of substrates after a chamber idling event, in accordance with an embodiment.

FIG. 2B is a line scan across the surface of a plurality of substrates after a chamber idling event and a warmup routine, in accordance with an embodiment.

FIG. 3A is a graph of a virtual sensor reading over the course of processing a plurality of substrates after a chamber idling event without a warmup routine, in accordance with an embodiment.

FIG. 3B is a graph of a virtual sensor reading over the course of processing a plurality of substrates after a chamber idling event with a warmup routine, in accordance with an embodiment.

FIG. 4 is a flow diagram of a process for recording parameters that correspond to an optimum chamber condition, in accordance with an embodiment.

FIG. 5 is a flow diagram of a process for warming up a chamber after a chamber idling event, in accordance with an embodiment.

FIG. 6 is a flow diagram of a process for warming up a chamber and initiating the processing of a lot of substrates after a chamber idling event.

FIG. 7 illustrates a block diagram of an exemplary computer system that may be used in conjunction with a processing tool, in accordance with an embodiment.

### DETAILED DESCRIPTION

Systems described herein include a process to mitigate first wafer effects in semiconductor processing chambers. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, cyclic conditioning recipes are currently used to mitigate first wafer effects (FWEs). However, such processes result in an increased cost for the operation of the chamber. Accordingly, embodiments disclosed herein include chamber warmup routines that are designed to mitigate the FWEs experienced after a chamber idling event. As such, the chamber may be kept at an idling condition without the need to run cyclic conditioning recipes. That is, there may be no need to process dummy wafers in order to keep the chamber at an optimal operating condition.

In an embodiment, the chamber warmup routine brings the chamber back to the optimum operating condition before a first substrate is loaded into the chamber. The optimum operating condition may be identified in previous iterations of the processing operation. For example, the system may monitor a number of substrates at the beginning of a lot of substrates. When the sensor data for subsequent substrates is within a stability specification (e.g., with a difference between 0.1% and 25%), the sensor data is stored for future use. The sensor data may be obtained from one or multiple sensors. In a particular embodiment, the sensor data at a given time is stored for future use. For example, it has been shown that replicating chamber conditions at the time substrates are inserted or withdrawn from the chamber is a good metric for determining when the chamber is properly warmed up.

In an embodiment, the stored sensor data may be used as a metric to determine when a warmup routine has returned the chamber to an optimum operating condition. In an embodiment, the sensor data may be a temperature value. In some embodiments, the sensor data may be a physical sensor that directly detects a condition of the chamber. In other embodiments, the sensor data may be sourced from a virtual sensor. A virtual sensor provides values that are calculated using source data from one or more physical sensors (e.g., flow sensors, pressure sensors, butterfly valve control angle, etc.). That is, a virtual sensor may provide sensor data of a condition of the chamber that is difficult or impossible to measure directly.

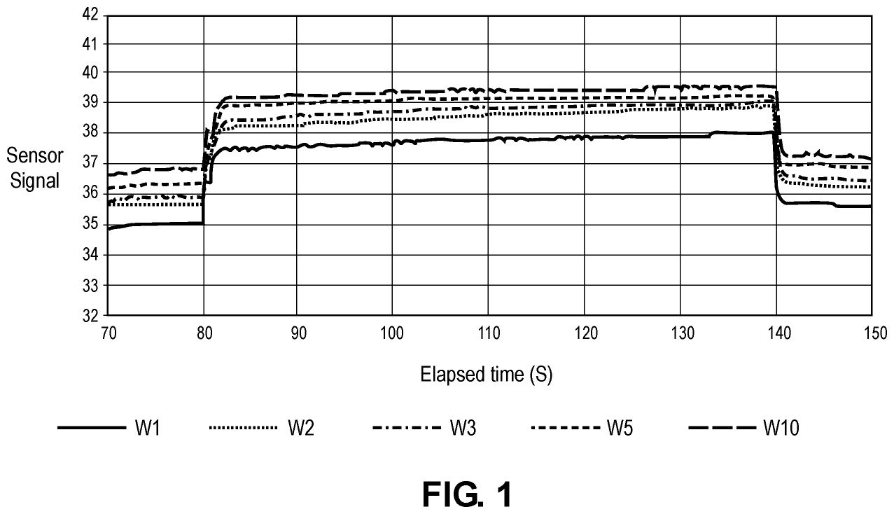

Referring now to FIG. 1, a graph of sensor data for the processing of a plurality of substrates is shown, in accordance with an embodiment. In a particular embodiment, the sensor used to provide the data in FIG. 1 is a change in the angular feedback for a butterfly valve during the first five substrates. In other embodiments, the sensor used to provide the data in FIG. 1 is a virtual sensor (e.g., a virtual angular feedback sensor). While an angular feedback sensor is provided as one example of the type of sensor, it is to be appreciated that other types of sensors (e.g., pressure sensors, gas flow rate sensors, temperature, etc.) or combinations of different sensors may be used in embodiments disclosed herein.

In an embodiment, each of the lines in the graph of FIG. 1 represent the sensor values for a different substrate that is processed. In an embodiment, the substrates that are processed may be the first substrates after a chamber idling event. As such, FWEs are demonstrated in FIG. 1. As shown in the graph of FIG. 1, the first substrate has a lower value than the subsequent substrates. Particularly, the substrates all show variation from each other. However, as more substrates are processed, the variation between the substrates reduces. For example, the difference between the first substrate W1 and the second substrate W2 is greater than the difference between the fifth substrate W5 and the tenth substrate W10.

The difference between the output values of the sensor in FIG. 1 results in non-uniform substrate outcomes. For example, film properties (e.g., thickness, composition, uniformity, etc.) may vary between the processed substrates. This variation may result in substrates that do not conform to a desired specification. As such, substrates may be scrapped or the substrate variation may cause device performance and yield issues later in the process flow.

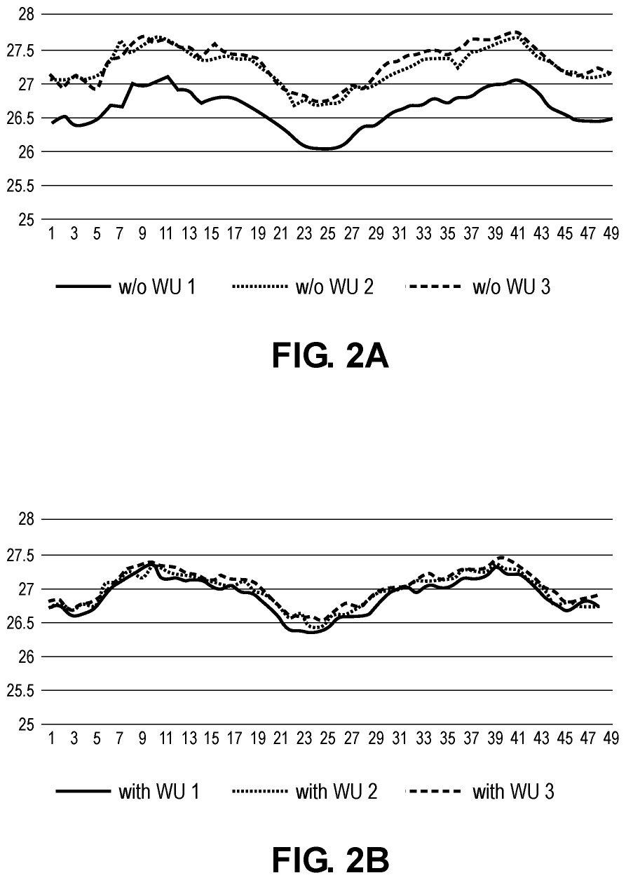

An example of the film non-uniformity produced by FWEs is shown in FIG. 2A. FIG. 2A is a line scan across the surface of a substrate (e.g., a 49 point line scan). As shown, the first substrate 1 (without warmup) has a significantly lower value than the second substrate 2 and the third substrate 3. In some instances the differences between the first substrate 1 and the second substrate 2 and the third substrate 3 may exceed allowable tolerances. As such, the first substrate 1 may need to be scrapped or reworked.

Accordingly, embodiments disclosed herein include a warmup routine that mitigates the FWEs shown in FIG. 2A. For example, FIG. 2B shows a line scan across the surface of substrates 1-3 when a warmup routine is used. As shown, the first substrate 1, the second substrate 2, and the third substrate 3 each have substantially similar outcomes. That is, the substrates 1-3 have a low variability. As such, the FWEs previously described are avoided.

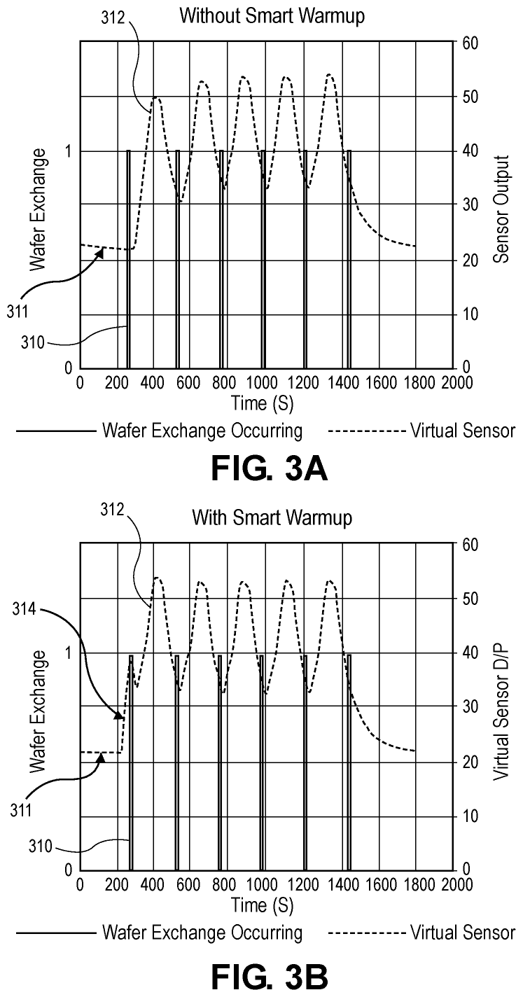

Referring now to FIG. 3A, a graph of a virtual sensor reading over the course of processing a plurality of substrates is shown, in accordance with an embodiment. Overlying the graph of the virtual sensor data is an indication of when substrates are inserted and/or withdrawn from the chamber. That is, peaks 310 correspond to the insertion and/or withdrawal of a substrate from the chamber. The first substrate insertion is implemented after an idling period 311. For example, the idling period may be any duration. In some embodiments, the idling period may be one or more minutes, one or more hours, or one or more days. As such, the first peak 312 of the virtual sensor may be different than the subsequent peaks. For example, the first peak 312 is lower than the subsequent peaks. As such, the first substrate may suffer from FWEs.

Referring now to FIG. 3B, a graph of a virtual sensor reading over the course of processing a plurality of substrates is shown, in accordance with an embodiment. The graph in FIG. 3B differs from the graph in FIG. 3A in that a warmup routine 314 is implemented before the first substrate exchange 310. As shown, the output of the virtual sensor increases before the first substrate exchange 310. The warmup routine 314 results in the subsequent peaks 312 of the virtual sensor data to be substantially uniform. As such, there are substantially no FWEs.

In an embodiment, the warmup routine may be tailored to provide a condition that is substantially similar to the condition of the chamber at subsequent instances of the substrate exchange. For example, the value of the virtual sensor is substantially similar at each instance of a substrate exchange. In some instances, the substrate exchanges occur at the tail end of each peak 312 of the virtual sensor readings. As such, the warmup routine 314 increases the output of the virtual sensor and allows for a brief decline in the output of the virtual sensor before increasing to form the next peak. Such an embodiment allows for the first substrate after an idling event 311 to be processed as if one or more substrates have been processed before the first substrate. Accordingly, FWEs are avoided.

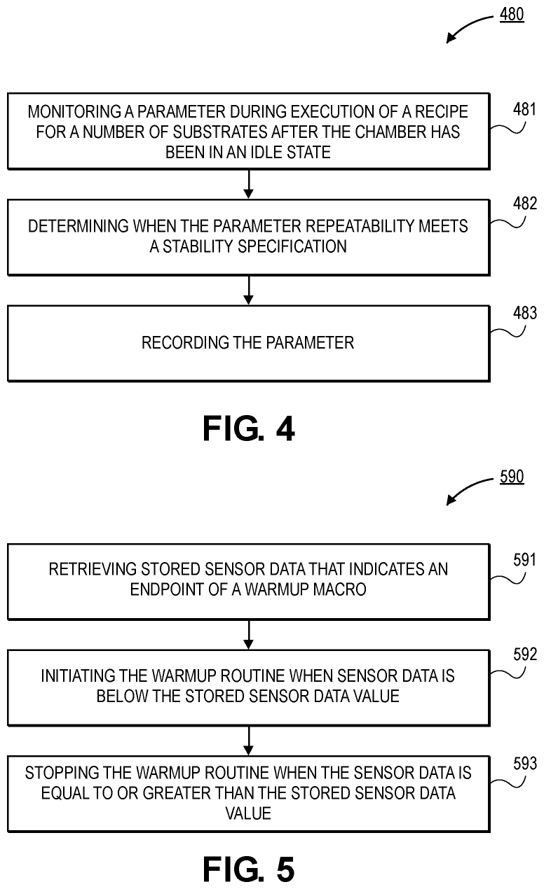

Referring now to FIG. 4, a flow diagram of a process 480 for learning an optimum chamber condition after an idling event is shown, in accordance with an embodiment. In an embodiment, the process 480 may begin after a chamber has been in an idling event. For example, the idling event may be a period of time (e.g., seconds, minutes, hours, or days) where the chamber has not processed any substrates. In some embodiments, there may be no substrates (e.g., dummy substrates) cycled through the chamber with a conditioning recipe during the idling event. As such, the cost of operating the chamber is reduced.

In an embodiment, process 480 may begin with operation 481, which comprises monitoring a parameter during execution of a recipe for a number of substrates at a beginning of a lot of substrates. In an embodiment, the recipe may be started without any warmup of the chamber. That is, it is expected that one or more of the substrates may exhibit FWEs. In an embodiment, the number of substrates may be three or more substrates. In some embodiments, the number of substrates may be up to twenty-five substrates. In a particular embodiment, the number of substrates may be five substrates.

In an embodiment, the parameter being monitored may be any condition of the chamber during the execution of the recipe. For example, the parameter may be a pressure, a temperature, a flow rate of one or more gasses, or the like. In some embodiments, a plurality of parameters may be monitored during operation 481. In an embodiment, the parameters may be detected by a physical sensor. In other embodiments, the parameters may be measured by a virtual sensor.

In an embodiment, the process 480 may continue with operation 482, which comprises determining when the parameter repeatability meets a stability specification. Parameter repeatability may refer to how consistent the monitored parameter is at a given point in the recipe. For example, it has been shown that high repeatability at or around the substrate exchange operation leads to more consistent substrate outcomes (e.g., uniform film properties). As such, the point in the recipe that is used to determine parameter repeatability may be at or around the substrate exchange operation.

In an embodiment, the stability specification refers to a percentage difference between subsequent iterations of the recipe. In some embodiments, the stability specification may be as stringent as approximately 0.1%. In other embodiments, the stability specification may be up to approximately 25%. In a particular embodiment, the stability specification may be approximately 3%. That is, at a particular time in the recipe (e.g., during or around the substrate exchange), the output value of the sensor (or virtual sensor) may be within the stability specification.

In an embodiment, process 480 may continue with operation 483, which comprises recording the parameter. That is, when the parameter meets the stability specification, the output of the sensor is recorded. The recorded parameter may be used as a benchmark to determine when a chamber is sufficiently warmed up. For example, in the case of a thermal process, an idling chamber may be heated up to a temperature consistent with the recoded parameter before starting to process substrates. In this manner, FWEs may be limited or completely avoided.

Referring now to FIG. 5, a flow diagram of a process 590 for warming up a chamber after an idling event is shown, in accordance with an embodiment. In an embodiment, the idling event may refer to a chamber that has not been recently used to process production substrates. In an embodiment, the idling event may have a duration of seconds, minutes, hours, days, or longer. During the idling event, there may not be a need to cycle non-production substrates (e.g., dummy substrates) during a conditioning recipe.

In an embodiment, process 590 may begin with operation 591, which comprises retrieving stored sensor data that indicates an endpoint of a warmup routine. In an embodiment, the stored sensor data may be from one or more physical sensors and/or one or more virtual sensors. In a particular embodiment, the stored sensor data may be generated using a process similar to the process 480 described in greater detail above. That is, the stored data may be data that indicates the chamber is properly warmed up in order to mitigate or eliminate FWEs. In some instances, the stored data may be referred to as a trained value or a setpoint value. It is to be appreciated that the endpoint of the warmup routine may be recipe specific. That is, the endpoint may be different for different process recipes. In some embodiments, the endpoint may be a process time, a process temperature, or any other process parameter or parameters.

In an embodiment, process 590 may continue with operation 592, which comprises initiating the warmup routine when sensor data is below a value of the stored sensor data. For example, the value may be a temperature in some embodiments. When the measured temperature (or calculated temperature using a virtual sensor) is below the value of the stored sensor data, the chamber may initiate one or more processes to increase the temperature to the value of the stored sensor data. For example, in a chamber for thermal processes, one or more lamps may be turned on to increase the temperature. In other embodiments, various processing operations such as turning on a plasma source, rotating a susceptor, raising and lowering pins, changing the flow of gasses into the chamber, changing pressures, and any other chamber control may be implemented in order to bring the chamber into a state that matches the trained setpoint value.

In an embodiment, process 590 may continue with operation 592, which comprises stopping the warmup routine when the sensor data is equal to or greater than the trained value. When the one or more sensors reach the trained value or trained values, the warmup operation is considered to be complete. That is, the chamber is in a state that substantially matches the state of a chamber continuously running the given recipe. As such, it is expected that when the first substrate is processed, the outcome will not exhibit any FWEs, or at least that the FWEs will be reduced in magnitude and/or duration.

It is to be appreciated that such processes (e.g., process 480 or process 590) may be executed in any type of processing chamber typical of semiconductor manufacturing environments. In a particular embodiment, the elimination of FWEs is implemented on a thermal chamber, such as a chamber implementing radical oxidation processes. In such an embodiment, the temperature at or around the time of the substrate exchange has been shown to strongly correlate to the presence or absence of FWEs. As such, by increasing the temperature to the match the temperature of subsequent substrate exchanges, the first substrate will be processed with minimal FWEs.

While embodiments with a thermal process are described in detail herein, it is to be appreciated that embodiments are not limited to such processing tools. For example, chambers that utilize plasma processes may also utilize one or more embodiments described herein. Additionally, while temperature is explicitly recited as one of the sensor (or virtual sensor) outputs, it is to be appreciated that different sensor types or combinations of different sensor types may be used in order to mitigate or eliminate FWEs of various types of semiconductor processing recipes in chambers that have been in an idle state.

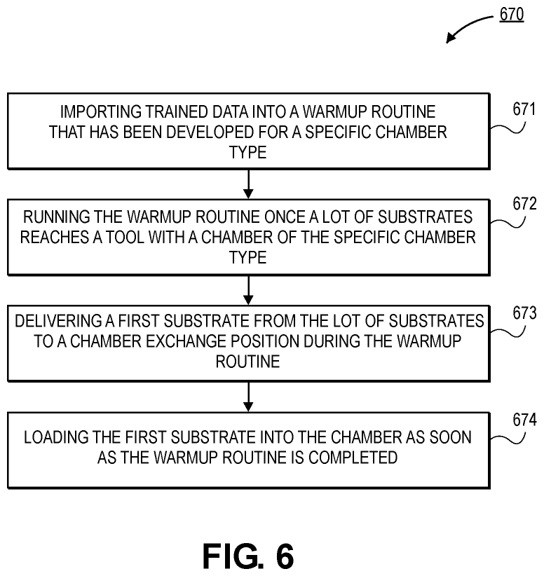

Referring now to FIG. 6, a flow diagram of a process 670 for automatically using a warmup routine is shown, in accordance with an embodiment. In such an embodiment, the operator of a processing tool enables the warmup feature as part of a recipe or process sequence. After the warmup feature is enabled, the tool automatically collects the critical sensor data for that recipe. When the stable sensor data value has been trained the value is stored in the readiness database. Every time that recipe is run, after a user defined maximum idle time (e.g., one or more minutes, one or more hours, etc.) the software will execute process 670.

In an embodiment, process 670 may begin with operation 671, which comprises importing trained data into a warmup routine that has been developed for a specific chamber type. In an embodiment, the trained data may be obtained using a process similar to the process 480 described in greater detail above.

In an embodiment, process 670 may continue with operation 672, which comprises running the warmup routine once a lot of substrates reaches a tool with a chamber of the specific chamber type. For example, the warmup routine may be initiated once a front opening unified pod (FOUP) reaches the tool, or when the FOUP door is opened. However, it is to be appreciated that the warmup routine may be initiated before the FOUP reaches the tool in some embodiments.

In an embodiment, process 670 may continue with operation 673, which comprises delivering a first substrate from the lot of substrates to a chamber exchange position during the warmup routine. Moving the first substrate into the exchange position allows for substrates to be processed immediately after the warmup condition is reached. As such, FWE are reduced.

In an embodiment, process 670 may continue with operation 674, which comprises loading the first substrate into the chamber as soon as the warmup routine is completed. In an embodiment, the first substrate is immediately loaded after the warmup routine is completed. That is, the end of the warmup routine is followed by an instruction to load the first substrate into the chamber. In other embodiments, the first substrate may be loaded into the chamber within a few seconds of completion of the warmup routine, or within a minute of completion of the warmup routine. After the first substrate is loaded into the chamber, the first substrate may be processed in accordance with the recipe.

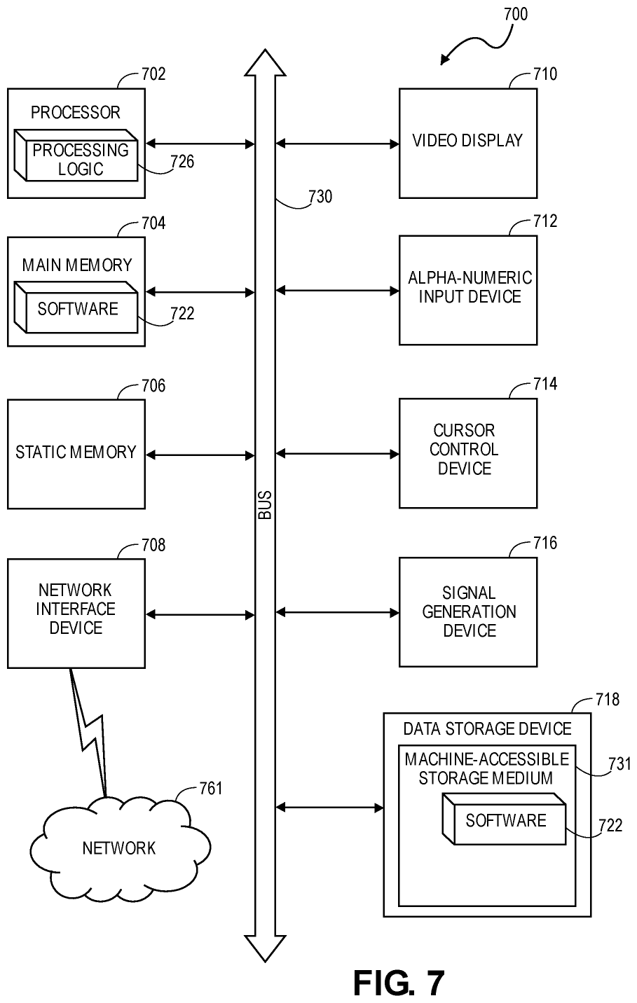

Referring now to FIG. 7, a block diagram of an exemplary computer system 700 of a processing tool is illustrated in accordance with an embodiment. In an embodiment, computer system 700 is coupled to and controls processing in the processing tool. Computer system 700 may be connected (e.g., networked) to other machines in a Local Area Network (LAN), an intranet, an extranet, or the Internet. Computer system 700 may operate in the capacity of a server or a client machine in a client-server network environment, or as a peer machine in a peer-to-peer (or distributed) network environment. Computer system 700 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 700, the term “machine” shall also be taken to include any collection of machines (e.g., computers) that individually or jointly execute a set (or multiple sets) of instructions to perform any one or more of the methodologies described herein.

Computer system 700 may include a computer program product, or software 722, having a non-transitory machine-readable medium having stored thereon instructions, which may be used to program computer system 700 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 700 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 700 may further include a system network interface device 708 for communicating with other devices or machines. The computer system 700 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 732 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 700, the main memory 704 and the system processor 702 also constituting machine-readable storage media. The software 722 may further be transmitted or received over a network 720 via the system network interface device 708. In an embodiment, the network interface device 708 may operate using RF coupling, optical coupling, acoustic coupling, or inductive coupling.

While the machine-accessible storage medium 732 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method for determining an optimum chamber condition, comprising:
monitoring a parameter during execution of a recipe for a number of substrates after the chamber has been in an idle state;
determining when a repeatability of the parameter meets a stability specification; and
recording the parameter.

2. The method of claim 1, wherein the number of substrates is up to twenty five substrates.

3. The method of claim 1, wherein the number of substrates is up to five substrates.

4. The method of claim 1, wherein the parameter is measured at or close to the start of a substrate exchange operation.

5. The method of claim 1, wherein the stability specification is between approximately 0.1% and approximately 25%.

6. The method of claim 5, wherein the stability specification is approximately 3%.

7. The method of claim 1, wherein the parameter is measured with a virtual sensor.

8. A method of warming up a chamber, comprising:
retrieving stored sensor data that indicates an endpoint of a warmup routine;
initiating the warmup routine when sensor data is below a value of the stored sensor data; and
stopping the warmup routine when the sensor data is equal to or greater than the value of the stored sensor data.

9. The method of claim 8, wherein the warmup routine comprises turning on one or more lamps.

10. The method of claim 8, wherein the warmup routine comprises initiating a plasma source.

11. The method of claim 8, wherein the sensor data is a calculated value based on the readings of two or more physical sensors.

12. The method of claim 8, wherein a substrate is loaded into the chamber after the warmup routine is stopped.

13. The method of claim 8, wherein the value of the stored sensor data is substantially equal to a value of the sensor at the time of a substrate loading event.

14. The method of claim 8, wherein the sensor data is a virtual temperature measurement.

15. The method of claim 8, wherein the method is executed after the chamber has been in an idling state.

16. The method of claim 15, wherein the idling state does not include cycling dummy substrates.

17. A method of warming up a chamber, comprising:
retrieving stored virtual sensor data that indicates an endpoint of a warmup routine, wherein the stored virtual sensor data is a calculated value based on the readings of two or more physical sensors;
initiating the warmup routine when virtual sensor data is below a value of the stored virtual sensor data, wherein the warmup routine comprises turning on one or more lamps; and
stopping the warmup routine when the virtual sensor data is equal to or greater than the value of the stored virtual sensor data.

18. The method of claim 17, wherein the method is executed after the chamber has been in an idling state.

19. The method of claim 18, wherein the idling state does not include cycling dummy substrates.

20. The method of claim 17, wherein the stored virtual sensor data is substantially equal to a value of the virtual sensor at the time of a substrate loading event.
